(19) United States
(12) Patent Application Publication
(10) Pub. No.: US 2026/0297408 A1
(43) Pub. Date: Oct. 1, 2026

(54) COOLING FLUID FOR ELECTRONIC DEVICES

(71) Applicant: CARGILL, INCORPORATED, Wayzata, MN (US)

(72) Inventors: Quynh Hoang, Andover, MN (US); Kevin Robert Wirtz, Eden Prairie, MN (US)

(73) Assignee: CARGILL, INCORPORATED, Wayzata, MN (US)

(21) Appl. No.: 19/479,076

(22) PCT Filed: Apr. 11, 2024
(86) PCT No.: PCT/US2024/023994

§ 371 Date: Oct. 27, 2025

Related U.S. Application Data
(60) Provisional application No. 63/464,337, filed on May 5, 2023.

(51) Int. Cl. C09K 5/10; G06F 1/20; H05K 7/20

(52) U.S. Cl. CPC C09K 5/10; G06F 1/20; H05K 7/20236

(57) ABSTRACT

The present disclosure relates to a cooling fluid for cooling an electronic device in a cooling system. The cooling fluid comprises one or more vegetable oils, one or more masking agents, and optionally, one or more coloring agents. A method of cooling an electronic device using the cooling fluid is also described herein.

### CROSS-REFERENCE TO RELATED APPLICATIONS

This application claims the benefit of U.S. Provisional application Ser. No. 63/464,337, filed May 5, 2023, which is incorporated by reference herein in its entirety.

### FIELD OF INVENTION

The present invention relates to a vegetable oil-based cooling fluid for cooling an electronic device.

### BACKGROUND

Vegetable oils such as natural esters have been used in cooling fluids to cool electronic devices in applications such as data center application. The use of natural esters in such applications has subtle challenges that would not be anticipated by most other applications.

If vegetable oils were utilized in computer data center applications, exposure of the vegetable oils to air will eventually lead to the release of oxidation byproducts (in ppm levels). These oxidation byproducts will cause the vegetable oils to emit odors that are sometimes described as fishy odors, fried food odors, or rancid oil odors. For workers, the constant exposure to any of these odors in the work environment can become uncomfortable. Additionally, at the normal operating ranges used for coolants for computer data center application coolants (e.g., 20° C. to 70° C.), the typical antioxidants (such as phenolic antioxidants) will not effectively minimize the formation of peroxides that can lead to the formation of the oxidation byproducts.

Reactive materials, such as acids that react with bases to form salts, or bleaching agents that react with sulfur-containing substances such as sulfides and mercaptans, can be used as odor control agents for masking odors. However, it is undesirable to form salt pairs and byproducts of reaction in electronics cooling fluids, as these materials can readily react with electronics components or react with the natural ester fluids to form byproducts that would change the properties of the coolant fluid (such as reducing the breakdown voltage and/or increase the dielectric dissipation factor exhibited by the coolant fluid). Also, absorbent materials such as clays, activated carbon, or cellulosic materials that are used to absorb odors are unsuitable for use in electronic coolant fluids, as they would have a tendency to block the cooling channels in electronics, clog the pumps and cooling systems, and otherwise damage the cooling systems components, such as seals. Further, clays, activated carbon and cellulosic materials absorb the cooling fluids and lead to losses of the fluids as well as causing system fouling. Absorbents used in filter cartridges for filtering the coolant fluids require additional pump power (and energy costs) and higher maintenance costs and are not effective in removing all oxidation byproducts from the vegetable oil.

Another means of covering undesired odors in commercial products like cleaners, petroleum oils and greases, animal odors, plant decay, or synthetically derived materials is to add large quantities of an aromatic compounds such that the aromatic compounds become the new detected odor. The selection of the aromatic compounds or mixtures of volatile compounds is based on abilities of the compounds to impart an overpowering fragrance into the environment that is perceived as pleasant. This overpowering effect is described in a European Patent Publication No. EP 0296117, where the minimum amount of fragrance compounds is described as 1,000 ppm.

Large quantities of aromatic compounds are usually required for masking undesirable odors. One major problem with the use of high levels of aromatics to perfume the air is that the odors of the aromatics, over long periods of time, become nuisance odors themselves. For example, workers would get tired of smelling the same odor day after day and develop nausea or sensitivity to the odors. These sensitivities are also manifested as an eventual aversion to the fragrance.

### SUMMARY

The present disclosure provides a cooling fluid for cooling an electronic device in a cooling system. The cooling fluid comprises one or more vegetable oils, one or more odor masking agents, and optionally one or more coloring agents. The odor masking agent is present at a concentration sufficient to mask one or more attributes of the cooling fluid without delivering an undesirable specific and/or an identifiable attribute profile of the odor masking agent. The odor masking agent at the desired concentrations will also not significantly degrade the electrical properties of the cooling fluid. The cooling fluid can also include other additives to enhance the performance characteristics of the fluid, such as antioxidants, crystal inhibition agents, flow additives, etc.

The present disclosure provides a cooling fluid for cooling an electronic device in a tank-type immersion cooling system, and in other cooling systems for electronic devices that can utilize a cooling fluid having a moderately low viscosity (e.g., typically from 25 to 40 cSt at 40° C., preferably from 27 to 40 cSt at 40° C. (for example from 30 to 37 cSt at 40° C.). The cooling fluid comprises a vegetable oil that has been refined bleached and deodorized (RBD) and further purified to improve the electrical properties of vegetable oil, a masking agent preferably selected from the group consisting of: sage oil, Spanish sage oil, rose essential oil (an oil distilled from the petals of Rosa damascene), lavender oil, chamomile oil, a blend of lavender oil and chamomile oil, a blend of white tea oil and aloe oil, and mixtures thereof, and optionally a blue dye (or in some instances a green dye as described below). The odor masking agent is present at a concentration sufficient to mask one or more odors that may be present in the vegetable oil (such as soybean oil) or may be produced over time due to oxidation of the vegetable oil, without producing a specific and/or readily identifiable odor profile of the odor masking agent. Typically, the concentration of the odor masking agent is 100 ppm or less.

If utilized, a blue dye imparts a teal color initially to the cooling fluid and may shift more to the green spectrum as the (vegetable oil (such as soybean oil) that comprises the cooling fluid ages over time. The teal color helps distinguish the cooling fluid from one or more other fluids that may be present in the electronic system. Also, the teal-colored cooling fluid is readily distinguishable from other fluids utilized in industrial settings, such as brake fluid (red), anti-freeze for automotive end-uses (yellow, orange, green), windshield fluid (blue), soaps (yellow, orange, blue), etc.

If utilized, a green dye as a coloring agent imparts a green to yellow-green color to the cooling fluid (as described below).

Where a yellowish color is acceptable, typically no coloring agent is utilized.

The present disclosure also provides a method of cooling an electronic device that comprises a step of contacting an electronic device with a cooling fluid in order to remove heat from the electronic device and expelling such heat in a heat exchanger that is operatively connected to the electronic device.

In one aspect, the cooling system and method for cooling the electronic components utilize a tank type cooling system where the circuit boards containing the electronic components are immersed in the tank/enclosure containing the cooling fluid. The tank/enclosure may be operatively connected to a heat exchanger that expels the heat generated by the circuit boards and picked up by the cooling fluid to the external environment. The cooling system of a tank type cooling system may comprise pumps and other mechanical devices to circulate the cooling fluid between the tank/enclosure and the external heat exchanger. The tank type cooling system may include an expansion tank that functions as a surge volume for the cooling fluid as it expands and contracts with temperature changes. The tank type system will also allow additional cooling fluid to be added to the cooling system as cooling fluid is depleted from the system. Tank type cooling systems are typically used for crypto mining and other data mining types of systems, where a group of data mining machines (such as S17 and S19 Antminer) are grouped together and located together (emersed in) a tank containing the cooling fluid.

In another aspect, the cooling system and method for cooling the electronic components comprises an external heat exchanger where heat produced by the electronic components can be expelled to the external environment operatively connected to housings or enclosures containing the electronic components. In this aspect a surge tank or coolant addition tank may be utilized as an expansion/contraction volume for (or tank for adding extra cooling fluid to) the cooling system. A pump or pumps (typically centrifugal) are utilized to circulate the cooling fluid through the enclosure containing the electronic components and out to the heat exchanger. Additional cooling fluid can be added to the surge tank to replenish cooling fluid as it is depleted from the cooling system. An example of this aspect of a cooling system is a system incorporating a rack or racks of blade-type computer servers that are stacked within the racks and connected to the cooling fluid through bayonette connectors (or some other type of connectors that allows the cooling fluid to enter and exit the blade server), which typically are located on the back, side, or front of the computer server. The servers are attached to the racks through movable hardware that allow each server to be individually removed from the rack. This allows for ready servicing and replacement of individual computer servers within the rack. The bayonette connectors (and similar rapid type connectors) facilitate each computer server unit to be quickly and efficiently connected and disconnected from the cooling system.

Tank type cooling systems and the other cooling systems described herein can be used for cooling other types of high performance computing systems known to one of skill in the art. Examples of high power computing systems include systems with high numbers of central processing units (CPUs) cores, high end graphical processing units (GPUs), and/or other types of processing units (or groups of processing units), such as artificial enabled computing units (AI units). Examples of chips used in these type of systems include CPUs and GPUs available from AMD and Intel, and GPUs and systems incorporating Tensor Cores available from Nvidia. The CPUs, GPUs, and other types of processing units typically are grouped together to carry out high level computing.

The present invention provides an improved vegetable oil-based cooling fluid for electronics, that effectively masks odors from the vegetable oil-based cooling fluid over time, without inducing strong and overpowering fragrances into the work environment.

### DETAILED DESCRIPTION

Reference will now be made in detail to certain aspects of the invention, examples of which are illustrated in part in specification, including the tables. While the disclosed subject matter will be described in conjunction with the enumerated claims, it will be understood that the information described in the specification (including the examples) are not intended to limit scope of the claims to what is disclosed in the specification.

Unless defined otherwise, all technical and scientific terms used herein have the same meaning as commonly understood by one skilled in the art to which this invention belongs. As used herein, each of the following terms has the meaning associated with it as defined below.

Unless expressly stated, ppm (parts per million), percentage, and ratios are on a by weight basis. Percentage on a by weight basis is also referred to as wt % below.

The term “for example.” “for instance,” “such as,” or “including” as used herein is meant to introduce examples that further clarify more general subject matter. Unless otherwise specified, these examples are provided only as an aid for understanding the applications illustrated in the present disclosure and are not meant to be limiting in any fashion.

In the methods described herein, the acts can be carried out in any order without departing from the principles of the disclosure, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process. The term “room temperature” or “RT”, as used herein, refer to a temperature between 21° C. to 22° C.

### Cooling Fluid

The present disclosure relates to a cooling fluid that is used for cooling an electronic device in a cooling system. The cooling fluid comprises one or more vegetable oils, one or more odor masking agents, and one or more coloring agents.

In one aspect, the present disclosure describes a composition designed as an aesthetically useable cooling fluid. The composition comprises two essential additive components, namely an odor masking agent and a coloring agent, that are mixed into a vegetable oil. Other additives, such as antioxidants, flow modifiers, or other additives can be added if desired. If present, in total the other additives typically make up less than one percent by weight (1 wt %) of the cooling fluid.

### Vegetable Oil

The term “vegetable oil”, as used herein, means an oil derived from a plant. Oils are compositions made up of triacylglycerols (“TAG”). Examples of vegetable oils useful in the present invention include those that will remain liquid at the application temperature (i.e., from 0° C. to 70° C.), including, but are not limited to, rapeseed oil (e.g., canola oil), corn oil, safflower oil, soybean oil, sunflower oil, and any mixtures thereof. Since the operational temperature of the application is in the range of 0° C. to 30° C. in the heat exchangers and 20° C. to 70° C. on the application side, oils with melting points below 0° C. (e.g., a melting point of from about −25° to −10° C., from −18° C. to −5° C.) are preferred. The preferred vegetable oils are soybean oil (melting point −10° C.), rapeseed oil and canola oil (melting point −10° C. to −20° C.), corn oil (melting point −11° C.), safflower oil (melting point −17° C.), and sunflower oil (melting point −17° C.). Details regarding some of the vegetable oils that may be utilized and their physical properties are listed below in Table 1-0.

TABLE 1-0

| | Melting Points | COC Flash Point | Fire Point |
|---|---|---|---|
| Preferred oils | (° C.) | (° C.) | (° C.) |
| Rapeseed oil | −10 to −21 | 327 | 350 |
| Canola oil | −10 to −21 | 327 | 350 |
| Corn oil | −11 | 325 | 354 |
| Safflower oil | −17 | 324 | >340 |
| Soybean oil | −10 to −6 | 320 | 355-365 |
| Sunflower oil | −17 | 316-320 | 341 |

Preferably, the vegetable oils are selected from soybean oil, rapeseed oil, sunflower oil, canola oil, or any combinations thereof. Due to its ready availability and low melting point, soybean oil is most preferred. Typically (and preferably), the vegetable oils are refined, bleached and deodorized (RBD) vegetable oils, which have or are further treated to have a dielectric dissipation factor of less than 2% at 90° C., an initial dielectric breakdown voltage of at least 15 kV when measured with a 2.0 mm gap distance, an acid value at or below 0.06 mg KOH/gram, and other properties which will provide a cooling fluid having the properties described herein.

Preferably, the new cooling fluid (and vegetable oil) exhibits an initial dielectric breakdown voltage of at least 15 kV when measured with a 2.0 mm gap distance, for example, at least 30 kV, at least 45 kV, as measured by ASTM D1816. The cooling fluid typically are usable in the cooling system for at least five (5) years, preferably at least seven (7) years, and most preferably at least ten (10) years. If desired, additional odor masking agents can be added to the cooling fluid contained in the cooling system as it ages over the life of the cooling fluid. The cooling fluid reaches its end of life when it exhibits a dielectric breakdown voltage of 7 kV or less when measured with a 1 mm gap distance, as measured by ASTM D1816.

Additionally, the cooling fluid when first introduced into the coolant system preferably exhibit a dielectric dissipation factor (tan δ) of less than 0.2% at 25° C., and a dielectric dissipation factor (tan δ) of less than 2.0 at 90° C. Dielectric dissipation factor is sometimes referred to as dissipation factor, will hereinafter be referred to as dielectric dissipation factor. The dielectric dissipation factor (tan δ) at 25° C. is measured in accordance with the method of ASTM D924, and the dielectric dissipation factor (tan δ) at 90° C. is measured in accordance with the method of IEC 60247. The dielectric dissipation factor (tan δ) is defined as the reciprocal of the ratio between the capacitive reactance of a sample to its resistance at 60 Hz. The dielectric dissipation factor (tan δ) is an indicator of the dielectric loss of the cooling fluid. For the materials of this document, dielectric dissipation factor (tan δ) is measured using a Eltel ADTR-2K Plus instrument available from Eltel Industries. For the Eltel ADTR-2K Plus instrument, about 28.6 gram of the fluid sample is required to fill in the calibrated test cell connected with 3 terminal configurations (low, ground and high voltage). The oil cell is heated in the test cell heater to the required temperature and test results are displayed by the display of the Eltel ADTR-2K Plus instrument.

The term “Flash Point” or “Flash Point Temperature”, as used herein, is the minimum temperature at which vapors of a volatile material can ignite in air when exposed to flame. The open cup flash point temperature is measured according to the method of ASTM D92 using a Cleveland Open Cup and is reported in degrees Celsius (° C.). The closed cup flash point temperature is measured according to the method of ASTM D93 using a Pensky-Martens Closed Cup (hereinafter closed cup flash point) and is reported in degrees Celsius (° C.). The closed cup flash point temperature of the cooling fluid should be at least 150° C., at least 200° C., preferably at least 245° C., and sometimes at least 265° C. The open cup Flash Point of the cooling fluid should be at least 150° C., at least 200′C, at least 250° C., at least 275° C., at least 300° C. (for example, at least 325° C.).

The “Fire Point” or “Fire Point Temperature” is determined by ASTM D92 using a Cleveland open-cup tester and is reported in degrees Celsius (CC). The Fire Point of the cooling fluid should be at least 150° C., preferably at least 200° C. more preferably at least 250° C., and even more preferably at least 300° C., and most preferably at least about 330° C.

The term “Acid Value” (AV), as used herein, is a measure of the residual hydronium groups present in a compound and is reported in units of milligram (mg) KOH/gram material. The Acid Value is determined as described in ASTM D974 as “Standard Test Method for Acid and Base Number by Color-Indicator Titration.” The maximum acid value for the cooling fluid when introduced into the cooling system is 0.06 mg KOH per gram of oil or less, preferably 0.05 mg KOH per gram oil or less, more preferably less than 0.03 mg KOH per gram oil.

The term “Iodine Value” (IV), as used herein, is the mass of iodine in grams that is consumed by 100 grams of a chemical substance. Iodine numbers are often used to determine the amount of unsaturation in fats, oils, and waxes. In fatty acids, unsaturation occurs mainly as double bonds which are very reactive towards halogens, iodine in this case. Thus, the higher the iodine value, the more unsaturation is present in the sample. The Iodine Value of a material can be determined by the method of (A.O.C.S. Cd1-25). Typically, the vegetable oils have an iodine values from 80 to 185 g I₂/100 g oil, preferably from 80 to 150 g I₂/100 g oil, more preferably from 90 to 145 g 12100 gram oil, and most preferably from 100 to 142 g I₂/100 g oil.

Moisture content in the cooling fluid is determined in accordance with IEC 60814. Typically, the moisture content of cooling fluid is less than 200 ppm, preferably less than 150 ppm, more preferably less than 100 ppm, and even more preferably less than 50 ppm.

Typically, refined, bleached, and deodorized (RBD) soybean oil that typically has been further processed to meet the electrical specifications and other properties set forth for the cooling fluid is used in the present invention. The RBD soy bean oil utilized typically have an open cup flash point of at least 310° C. a closed cup flash point of at least 250° C. a fire point of at least 150° C. (for example at least 250° C., at least 300° C., and/or at least 345° C.), a viscosity of from about 30 to 35 cSt at 40° C., a moisture content of from about 10 to 200 ppm, an acid value of less than about 0.06 milligrams KOH/gram oil, and an iodine value of 120 to 145 g 12100 g. Preferably, the RBD soybean oil has an open cup flash point of at least 320° C. and a closed cup flash point of at least 230° C., 240° C., 245° C., and often at least 265° C. Due to the low concentrations of the odor masking agent and coloring agent utilized, a soybean oil having the properties set forth above, will provide a cooling fluid having equivalent properties, with the closed cup of the cooling fluid having a closed cup flash point of at least 230° C., 240° C., and preferably at least 245° C.

In another aspect, RBD rapeseed oil that typically has been further processed to meet the electrical specifications and other properties set forth for the cooling fluid can be used in the present invention. The RBD rapeseed oil utilized typically has an open cup flash point of at least 300° C. a closed cup flash point of at least 250° C., a fire point of at least 150° C. (for example at least 250° C., at least 300° C., and/or at least 345° C.), a viscosity of from about 34 to 40 cSt at 40° C., a moisture content of from about 10 to 200 ppm, an acid value of less than about 0.06 milligrams KOH/gram oil, and an iodine value of 90 to 120 g I₂/100 g. Due to the low concentrations of the odor masking agent and coloring agent utilized, a rapeseed oil having the properties set forth above, will provide a cooling fluid having equivalent properties, with the closed cup of the cooling fluid having a closed cup flash point of at least 230° C., 240° C., and preferably at least 245° C.

In another aspect, RBD sunflower oil that typically has been further processed to meet the electrical specifications and other properties set forth for the cooling fluid can be used in the present invention. The RBD sunflower oil utilized typically has an open cup flash point of at least 275° C., a closed cup flash point of at least 250° C., a fire point of at least 150° C. (for example at least 250° C., and/or at least 300° C.), a viscosity of from about 30 to 35 cSt at 40° C., a moisture content of from about 10 to 200 ppm, an acid value of less than about 0.06 milligrams KOH/gram oil, and an iodine value of 125-136 g I₂/100 g. Due to the low concentrations of the odor masking agent and coloring agent utilized, a sunflower oil having the properties set forth above, will provide a cooling fluid having equivalent properties, with the closed cup of the cooling fluid having a closed cup flash point of at least 230° C., 240° C., and preferably at least 245° C.

In another aspect, RBD corn oil that typically has been further processed to meet the electrical specifications and other properties set forth for the cooling fluid can be used in the present invention. The RBD corn oil utilized typically has an open cup flash point of at least 250° C., a closed cup flash point of at least 230° C. a fire point of at least 150° C. (for example at least 250° C., at least 300° C., and/or at least 345° C.), a viscosity of from about 32 to 38 cSt at 40° C., a moisture content of from about 10 to 200 ppm, an acid value of less than about 0.06 milligrams KOH/gram oil, and an iodine value of 107 to 135 g I₂/100 g. Due to the low concentrations of the odor masking agent and coloring agent utilized, a corn oil having the properties set forth above, will provide a cooling fluid having equivalent properties, with the closed cup of the cooling fluid having a closed cup flash point of at least 230° C., 240° C., and preferably at least 245° C.

In another aspect, RBD canola oil that typically has been further processed to meet the electrical specifications and other properties set forth for the cooling fluid can be used in the present invention. The RBD canola oil utilized typically has an open cup flash point of at least 300° C., a closed cup flash point of at least 250° C. a fire point of at least 150° C. (for example at least 250° C., at least 300° C., and/or at least 345° C.), a viscosity of from about 33 to 38 cSt at 40° C., a moisture content of from about 10 to 200 ppm, an acid value of less than about 0.06 milligrams KOH/gram oil, and an iodine value of 105 to 126 g I₂/100 g. Due to the low concentrations of the odor masking agent and coloring agent utilized, a canola oil having the properties set forth above, will provide a cooling fluid having equivalent properties, with the closed cup of the cooling fluid having a closed cup flash point of at least 230° C., 240° C., and preferably at least 245° C.

Preferably, the cooling fluid (and vegetable oil) have an auto-ignition temperature of at least 200° C., at least 250° C., or an auto-ignition temperature of at least 300° C. Auto-ignition temperature is measured in accordance with the method of ASTM E659.

Typically, the vegetable oils used are first processed to refined, bleached and deodorized (RBD) quality, then treated with a selection of clays to meet the desired electrical properties, mentioned above (e.g., to meet the physical and electrical properties necessary for a cooling fluid into which electronic components are immersed). Examples of the clays utilized to purify the vegetable oils include, but are not limited to, clays such as bentonites (B-80), magnesium silicates, bauxites, attapulgites, activated palygorskites, montmorillonites, kaolin clays (sometimes referred to as white clay), and other materials such as, activated carbon (that is preferably free of dust modifiers), silicates, diatomites, activated silicas, and mixtures thereof.

The clays will also typically reduce the unwanted colors of red and yellow tint. The vegetable oils are further processed to reduce moisture content to the levels mentioned above using drying methods know to one of skill in the art, such as degassing the vegetable oils using a nitrogen sparge at between 60° C. and 90° C., or using degassing vacuum processing equipment.

Typically, the vegetable oil is treated to reduce the color of the RBD vegetable oil to a value of Lovibond RYBN Colour standard of the following: Lovibond Red less than 2.0 (for example from 0.5 to 2.0) and a value of Lovibond Yellow below 20 (for example 3 to 15). Reducing the color of the RBD vegetable oil to these values will provide a cooling fluid having the desired optical clarity useful for use in tank type cooling systems. The Lovibond RYBN Colour standard is defined by AOCS Cc 13e-92. Examples of materials and methods for reducing the color of the vegetable oils, include, but are not limited to activated carbon (that is preferably free of dust modifiers), bleaching clays such as bentonites (B-80), kaolin clays (white clay), diatomites, activated palygorskites, activated silicas, bauxite, and mixtures thereof.

### Odor Masking Agent

In the cooling fluid of the present invention, the odor masking agent masks undesirable odor(s) of the cooling fluid that can arise over time. In one aspect, the odor masking agent useful in the present invention is an aromatic or fragrant compound that can mask odors emitted by the vegetable oil in the cooling fluid, especially those that are emitted over time as the vegetable oil ages and oxidizes. Examples odor masking agents that may be utilized typically include sage oil, Spanish sage oil, rose essential oil, lavender oil, chamomile oil, a mixture of lavender oil and chamomile oil, a blend of white tea oil and aloe oil, and any combinations of the foregoing. The odor masking agent preferably comprises sage oil, Spanish sage oil, rose essential oil, a blend of white tea oil and aloe oil, and mixtures thereof. The odor masking agent most preferably comprises sage oil and/or Spanish sage oil. Sage oil and Spanish sage oil are most preferred due to their ability to be added at up to 95 ppm to 100 ppm in the vegetable oil without producing an unacceptable odor profile, while also being effective as an odor masking agent at low concentrations (for example about 5 ppm). Therefore, they can be utilized at a wide concentration range that will provide for effective odor masking over time. Vegetable oils containing the preferred odor masking agents all exhibit excellent thermal stability and do not emit unacceptably unpleasant or otherwise unacceptable odors when heated to 60° C. for two (2) hours. Sage oil and Spanish sage oil are available from suppliers known to one of skill in the art, examples of sage oil available include, but are not limited to, sage oil from Bulk Apothecary, sage oil extracted with sunflower oil from Naturex (trade name Sage Dalmation oleoresin OS) and sage oil from Mayam EU, or Elemental SRL of Romania.

The masking agent typically is present at a concentration sufficient to mask one or more odor attributes of the cooling fluid without delivering a specific and/or an identifiable attribute profile of the masking agent. In other words, the masking agent should have a low enough volatility so that its level can be minimized to mask any undesirable odor (e.g., a fishy odor, a fried oil odor, a rancid oil odor) emitted from the vegetable oil of the cooling fluid, while the original odor or fragrance of the masking agent is being kept at a low level that would not be readily recognizable by the user, and/or being kept at a level acceptable to the user. The odor masking agent should be capable of not only masking odors that are initially in the cooling fluid, but also masking odors that are generated by the cooling fluid when in use over time (for example typically at least five (5) years, preferably at seven (7) years, more preferably at least ten (10) years and typically from three (3) to ten (10) years), when utilized at low concentrations as describe herein.

“A specific and/or an identifiable attribute profile of the masking agent”, as used herein, refers to a profile of odor/smell/fragrance of the masking agent that is originally present and definable or recognizable by a user. For example, rose essential oil, when used at higher concentrations has a specific and/or identifiable attribute profile of a smell of rose, but is not perceived as a rose smell when utilized at concentrations described below, but is still at these low concentrations able to mask unpleasant odor produced in the vegetable oil over time.

It has surprisingly been found that the odor masking agent can be used at a concentration of less than 100 ppm, such that when added to the cooling fluid, the undesirable odor of the vegetable oil of the cooling fluid over time is masked from perception. Just as people in their home or workspace do not perceive the unique atmosphere of their home or workspace, the newly emitted odor of the cooling fluid is changed, so that combination of the unpleasant odor of the vegetable oil and the fragrance of the odor masking agent have a new sensory profile that is not unpleasant and does not have a specifically recognized odor profile.

In one aspect, a Sage oil from various sources of sage including, but not limited to, sage bush plant, Spanish sage, and sage spice feedstocks is utilized as the odor masking agent. Sage oil and Spanish sage oil are roughly equivalent in their masking activity. Sage oil and Spanish sage oil, have a very definitive odor in their concentrated form. Spanish sage oil and sage oil typically are preferably utilized as the odor masking agent at from 2 ppm to 85 ppm in the cooling fluid, preferably from 2 ppm to 80 ppm in the cooling fluid. In some instances, the concentration of sage oil and/or Spanish sage oil are from 5 to 20 ppm, from 5 to 25 ppm, from 10 to 45 ppm, from 10 ppm to 70 ppm, from 15 ppm to 65 ppm, from 20 ppm to 60 ppm, from 25 ppm to 55 ppm, or from 30 ppm to 50 ppm. In some instances, in order to provide more long lasting results, the sage oil and Spanish sage oil can be utilized at higher levels, for example from 50 ppm to 75 ppm, 55 ppm to 75 ppm, 60 to 75 ppm or 60 ppm to 70 ppm, based on the total weight of the cooling fluid.

It has surprisingly been found that when the odor masking agents are present within cooling fluid at the concentrations described above, an odor that identifies the odor masking agent is not perceived in the cooling fluid or the headspace of the cooling fluid; rather, a slight and non-offensive undefinable natural odor is barely perceived. Vegetable oil odor, whether it be mild, fishy, or that of a thermally degraded oil will be masked by the masking agent at as low as 2 ppm (preferably at least 5 ppm), of use with new, old, or used vegetable oils. The resulting oil odor does not permeate into the surrounding environment because it is at such low concentration and does not present a strongly fragrant odor in the headspace. The concentration of the masking agent in the cooling fluid is low such that emission of the fragrance from the masking agent into the headspace and surrounding environment remains low, but still the masking agent is capable of masking any oxidation byproducts released by the vegetable oils because the odor masking agent and the vegetable typically slowly vaporize at a similar rate and concentration over time. The odor masking agent remains effective, even when the cooling fluid is maintained within the typical operating temperatures for the cooling system (e.g., 20° C. to 70° C.). Preferably, the upper temperature limit for the cooling system is 60° C. or below.

In one aspect, sage oil comprises a mixture of compounds that includes, but is not limited to, alpha and beta thujones (around 30 to 35% by weight), camphor, and cineole 1-8. These compounds, either individually or in mixtures with other compounds in varying compositions, may also be considered as masking agent for the cooling fluid of the present invention.

In another aspect rose essential oil is utilized as the odor masking agent. The cooling fluid typically comprises from 2 ppm to 35 ppm rose essential oil, preferably from 5 ppm to 30 ppm rose essential oil, (for example from 5 ppm to 20 ppm). In some instances, the cooling fluid comprises from 10 ppm to 25 ppm (for example, from 15 ppm to 25 ppm, from 15 ppm to 20 ppm) rose essential oil.

In another aspect lavender oil, chamomile oil, or a blend of lavender oil and chamomile oil are utilized as the odor masking agent. The cooling fluid typically comprises from 2 ppm to 35 ppm lavender oil, chamomile oil, or a blend of lavender oil and chamomile oil, preferably from 5 ppm to 30 ppm (for example from 5 ppm to 20 ppm) lavender oil, chamomile oil, or a blend of lavender oil and chamomile oil. In some instances, the cooling fluid comprises from 10 ppm to 25 ppm (for example, from 15 ppm to 25 ppm, from 15 ppm to 20 ppm) lavender oil, chamomile oil, or a blend of lavender oil and chamomile oil.

In another aspect a blend of white tea oil and aloe oil is utilized as the odor masking agent. A blend of white tea oil and aloe oil is preferably utilized as the odor masking agent at from 2 ppm to 85 ppm in the cooling fluid, preferably from 2 ppm to 80 ppm in the cooling fluid. In some instances, the concentration of the blend of white tea oil and aloe oil is from 5 ppm to 70 ppm, (for example 5 ppm to 20 ppm) from 15 ppm to 65 ppm, from 20 ppm to 60 ppm, from 25 ppm to 55 ppm, or from 30 ppm to 50 ppm. In some instances, in order to provide more long lasting results the blend of white tea oil and aloe oil can be utilized at higher levels, for example from 50 ppm to 75 ppm, 55 ppm to 75 ppm, 60 to 75 ppm or 60 ppm to 70 ppm, based on the total weight of the cooling fluid.

### Coloring Agent

A coloring agent is optionally utilized in the cooling fluid of the present invention. A coloring agent can impart a specific color that distinguishes the cooling fluid from one or more fluids present in a cooling system (or in the environment where the cooling system is located).

Preferably, the coloring agent is oil soluble. Oil-insoluble pigments, even if finely ground to submicron particle sizes, can accumulate on electronic circuits, and may cause negative interactions with the electronic devices and impede the dielectric properties of the cooling fluid.

A “oil soluble” coloring agent, as used herein, means that the coloring agent is at least ninety nine percent (99%) soluble in the vegetable oils at the operating temperatures of the cooling system (e.g., 20° C. to 70° C.). The coloring agent when used at the appropriate concentration will allow users to readily distinguish the cooling fluids from other fluids present or nearby the cooling system.

In one aspect, the color utilized for the coloring agent of the invention typically is a shade of blue. Vegetable oils, generally start with a yellow coloration that deepens with aging. The addition of a blue shaded coloring agent will interact with the natural coloration of the vegetable oil over time to produce a cooling fluid with a color from greenish-blue to blue (preferably green-blue initially, and more preferably, a teal-color initially), which will turn more greenish over time as the vegetable oil yellows. At the end of life of the cooling fluid, the color of the cooling fluid will be greenish-blue to green, or yellow-green. A cooling fluid that is teal initially and that turns a more greenish blue over time is advantageous in differentiating the cooling fluid from fluids having yellow coloration. Such as yellow fluids used for hazardous fluids, such as water ethylene-glycol solutions utilized for cooling engines and other devices. Additionally, ethylene-glycol aqueous solutions are often utilized in heat exchangers, which may serve to remove heat from the cooling fluid through a heat exchanger. If a leak occurs in the heat exchanger, the color of the ethylene-glycol would be detectable due to a change in color of the cooling fluid. And, a greenish blue or teal cooling fluid initially will also distinguish from cooling fluids and other fluids that are green. Blue dyes for use as coloring agents are available from suppliers known to one of skill in the art, examples of blue dyes include, but are not limited to, blue dye C.I. Solvent Blue 104 available from Aakash Chemicals (trade name Akasol Blue 2BS) and blue dye available from Clariant (trade name Sovaperm Blue 2B-CN).

Thus, the color imparted by the coloring agent to the cooling fluid of the present invention can differentiate the cooling fluid from other fluids utilized in industrial and electronic settings. In one aspect, greenish blue color may be desirable as it is generally perceived as an environmentally friendly color. In another aspect, a teal color may be desirable as it is perceived as a cool color. Preferably, the blue dye coloring agent imparts a range of color from teal-green, to teal, and to teal-blue to the cooling fluid both initially and over time. More preferably, the coloring agent imparts an initial teal color to the cooling fluid.

In an alternative aspect, the cooling fluid is green initially. This green color can be achieved by using the same blue coloring agent as utilized for the greenish-blue or teal cooling fluids, but utilized at lower concentration (for example from 0.4 ppm to less than 3.2 ppm (e.g., from 0.5 ppm to 1.5 ppm) of the blue dye described herein; or, a different coloring agent may be utilized, such as Solvent Green No 3 dye (available from Aldrich Chemical) or Green 6 dye (available from Roha Chemical). The concentration of the green dyes typically will be from 0.4 ppm to 6 ppm (e.g., from 0.4 ppm to 5 ppm, preferably from 0.4 ppm to 3 ppm, and more preferably from 0.4 ppm to 2 ppm, and further more preferably from 0.4 ppm to 1 ppm). When used at these levels, the cooling fluid will possess a high enough color intensity, but a user will still be able to see through the fluid contained in a tank or other enclosure and be able to identify other mechanical or electrical parts of the cooling system. In this alternative aspect, the cooling fluids are initially green, typically will turn yellow green by the end of life.

It is also important for the cooling fluid to maintain a certain translucency level. Once the fluid becomes opaque, components in a cooling system cannot be seen when attempting to service or read labels on the device.

In one aspect, the coloring agent is present at a concentration sufficient to impart a color to the cooling fluid while maintaining a translucency level for the cooling fluid, such that the cooling fluid is capable of being seen through. In other words, the coloring agent should have a low enough concentration to impart a desirable color to the cooling fluid, while the cooling fluid is still translucent enough to be seen through. It is important for the cooling fluid to keep a certain translucency level in, for example, enhancing the servicing of the electronic device and the cooling system. Typically, the coloring agent is utilized at less than 15 ppm, preferably less than 6.0 ppm.

Preferably, the desirable color of the cooling fluid imparted by the coloring agent is teal-green, teal, or teal-blue. More preferably, the desirable color of the cooling fluid imparted by the coloring agent is teal. In order to obtain the desired teal-blue color or greenish-blue color, the blue dye typically is used at concentrations from 3.2 ppm to 7.0 ppm, from 3.2 ppm to 6 ppm, from 3.2 ppm to 5 ppm, from 3.2 ppm to 4.6 ppm, and/or from 3.8 ppm to 4.4 ppm in the cooling fluid.

The color of the cooling fluid typically can be expressed using the Hunter color scale or CIE 1976 (CIELAB) color system scale which both use three coordinates (or values) to define color profile. For both the Hunter and the CIELAB scales, the “L” coordinate represents brightness and can assume values between 0 (for black) and 100 (for white); the “a” value represents the red component (a>0); and the “b” value represents the yellow component (b>0).

When a blue dye is utilized, the cooling fluid has a range of color, imparted by the coloring agent, for example for a cooling fluid having a range of color from teal-green through teal to teal-blue, the Hunter color values typically will be a “L” value from 91.8 to 94.9, an “a” value from −6.5 to −5.2, and a “b” value from −2.6 to 2.4. For example, for teal-green color using the Hunter color scale, typically a “L” value from 93.6 to 94.9, an “a” value from −6 to −5.2, and a “b” value from 0 to 2.4; for teal color using the Hunter color scale, typically a “L” value from 92.2 to 93.4, an “a” value from −6.3 to −5.6, and a “b” value from −1.3 to 1.4; and for a teal-blue color using the Hunter color scale, typically a “L” value from 91.8 to 93.9, an “a” value from −6.5 to −5.9, and a “b” value from −2.6 to 0.4. Preferably, the cooling fluid has a teal color that is represented by Hunter color scale as a “L” value from 92.2 to 93.4, an “a” value from −6.3 to −5.6, and a “b” value from −1.3 to 1.4.

In the alternative aspect when a blue dye is utilized to obtain a greenish colored cooling fluid having a color from yellow-green to green the color values will typically be represented by the Hunter color scale by a “L” value typically 97.4 and above (for example from 97.4 to 100), an “a” value from −6.6 to −4.2, and a “b” value from 2 to 14.5). For example, the yellow-green color typically is represented by the Hunter color scale by a “L” value from 97.4 and above (from 97.4 to 99), an “a” value from −6.6 to −5.1, and a “b” value from 8.3 to 14.5); and a green color typically is represented by the Hunter color scale by a “L” value from 95.0 to 99, an “a” value from −5.1 to −4.2, and a “b” value from 2.0 to 8.3.

If a green colored dye is utilized to obtain a green colored cooling fluid the green color typically is represented by the Hunter color scale with a “L” value from 94.0 to 100, an “a” value from −9.3 to −2.9, and a “b” value from −0.2 to 5.3.

Preferably, the coloring agent in the present invention is a blue dye. Since the vegetable oils present in the cooling fluid of the present invention are naturally tinged with a yellow color, a coloring agent in blue can impart a teal or a teal-blue color to the cooling fluid.

If utilized, the concentration of the blue dye and/or green dye typically are utilized from 0.4 ppm to less than 15 ppm. The concentration of the dye utilized preferably is from 0.4 ppm to 6 ppm, and more preferably from 0.4 ppm to 5.7 ppm for the blue dye and typically in the ranges listed above if a green dye is utilized, all based on the dye type and total weight of the cooling fluid, with the most preferred concentration depending on the desired color of the cooling fluid, as described above. When used at these levels, the cooling fluid will possess a high enough color intensity, but a user will still be able to see through the fluid contained in a tank or other enclosure and be able to identify other mechanical or electrical parts of the cooling system.

### Other Ingredients

In one aspect, the cooling fluid of the present invention may further comprise antioxidants, which, if present, typically are present at from 0.15 to 0.55 percent by weight of the cooling fluid. Preferably, the combined concentration of any additives other than the coloring agent and odor masking agent is less than 1.0 percent by weight of the cooling fluid.

In one aspect, polar materials, including but not limited to, fatty acids, fatty acid methyl esters, mono-acylglycerides, and di-acylglycerides, are minimized in the cooling fluid of the present invention. This will aid in the cooling fluid to have the electrical/dielectric properties described herein.

### Composition and Properties of Cooling Fluid

In one aspect, a composition of the cooling fluid of the present invention comprises: a soybean oil, a sage oil, and a blue dye. The cooling fluid can be used for cooling an electronic device in an electronic cooling system, such as a tank-type immersion cooling system.

In one aspect, the sage oil is present at a concentration sufficient to mask one or more odors of the soybean oil without delivering a specific and/or identifiable odor profile of the sage oil. The concentration of sage oil is in a range of 2 ppm to 85 ppm in the cooling fluid, preferably from 2 ppm to 80 ppm (for example from 5 ppm to 20 ppm) in the cooling fluid. In some instances, the concentration of sage oil and Spanish sage oil are from 5 ppm to 25 ppm, from 10 ppm to 45 ppm, from 10 ppm to 7060 ppm, from 25 ppm to 55 ppm, or from 30 ppm to 50 ppm based on the total weight of the cooling fluid.

Use of a blue dye and/or green dye as a coloring agent will assist to distinguish the cooling fluid from other fluids that may be used with or around a cooling systems as described herein, and help identify leakage of other fluids into the cooling system, or the inappropriate fluids in the cooling systems.

The concentration of the blue dye is in a range of 0.4 to 15 ppm, preferably 0.4 ppm to 7 ppm, or more preferably 0.4 ppm to 6 ppm based on the total weight of the cooling fluid. The concentration of the blue dye that is utilized will depend on the desired color of the cooling fluid, as described above.

The cooling fluid of the present invention exhibits a minimum breakdown voltage of at least 15 kilovolts (kV) when measured with a 2.0 mm gap distance. Typically, the cooling fluid exhibits a breakdown voltage of from 15 (kV) to 45 kV measured at 20°-22° C. when measured with a 2.0 mm gap distance, and preferably a breakdown voltage of at least 35 kV measured at 20° to 22° C. The breakdown voltage is determined in accordance with ASTM D1816-12 as “Standard Test Method for Dielectric Breakdown Voltage of Insulating Liquids Using VDE Electrodes”.

Mineral oils have generally been used as a major ingredient in conventional cooling fluids for cooling electronic devices. However, mineral oils are not good at tolerating water and potential problems such as shorting out the electronic devices would arise when mineral oils are used at a concentration of 100 ppm or above. It has been surprisingly discovered in the present invention that the vegetable oils in the cooling fluid can tolerate water ingress into the cooling system of up to 2.3 wt. % without causing electrical failures in electronic devices. This can offer protection against leaks in heat exchange systems, such as water-cooling system that is common for cooling electronic devices.

A second advantage of using a cooling fluid based on vegetable oils over conventional petroleum-based synthetic oils (such as polyalphaolefins (PAOs), gas to liquid oils (GTL), and mineral oils), in cooling electronic devices is that cooling fluids based on vegetable oils have higher flash points than synthetic oils and mineral oils. For example, soy-bean oil as used the cooling fluid of the present invention has a flash point (open cup flash point) of about 320° C., which is much higher than the highest possible flash point of 220° C. for conventional petroleum-based mineral oils and synthetic oils, such as polyalphaolefins. As described above, a flash point is the lowest temperature at which vapors of a volatile material can ignite in air when exposed to flame; thus, vegetable oil is a safer choice than PAOs and mineral oils in cooling electronic devices.

### Applications

In accordance with the present disclosure, a method of cooling an electronic device is provided that comprises contacting an electronic device with a cooling fluid of the present invention. In one aspect, the electronic device may be immersed in the same enclosure with a cooling fluid, or the electronic device may be located in a different enclosure and in fluid connection with the cooling fluid. In either configuration, the electronic device can function electronically while still operating at temperatures that protect the internal materials from heat damage (or thermal throttling), where the heat generated by the electronic device can be transferred to and carried away by the cooling fluid.

In one aspect, the electronic device may include, but not limited to, a computer server, or a computer work station, or a group of computer servers, or a group of computer work stations. Examples of such computer servers and work stations include crypto mining systems, cloud services and datacenters that utilized numerous computer servers and/or computer work stations. In one aspect the cooling system cools a group of rack mount computer servers located in a computer server farm, where the rack mount servers (or blades) connect into the cooling system through the use of bayonet type connectors that allow the cooling system containing the circulating cooling fluid to be readily connected to the rack mount server blades so that the circulating cooling fluid can remove heat from the server blades.

In one aspect, the enclosure is a tank type immersion cooling system, where the computer board or servers are contained within the tank and immersed within the cooling fluid.

Additional examples of where the cooling fluid can be utilized include high-performance computing facilities, electrical vehicle charging stations, artificial intelligence computing centers. The cooling fluid may also be utilized to cooling electrical batteries in over-the-road vehicles, such as cars.

### EXAMPLES

The invention is further described in detail by reference to the following experimental examples. These examples are provided for purposes of illustration only and are not intended to be limiting unless otherwise specified. Thus, the invention should in no way be construed as being limited to the following examples, but rather should be construed to encompass any and all variations which become evident as a result of the teaching provided herein.

### Example 1—Study on Properties of Cooling Fluid

A mixture of refined bleached and deodorized (“RBD’) soybean oil (available from Cargill, Incorporated), blue dye (C.I. Solvent Blue 104) from Clariant (trade name Sovaperm Blue 2B-CN), and sage oil from Bulk Apothecary, were stirred for at least 30 minutes in a reactor to form the cooling fluid. The final concentrations of the blue dye was about 4.0 to 4.5 ppm, and the final concentrations of sage oil was about 45 ppm, based on the total weight of the cooling fluid. The water content of the cooling fluid is less than 200 ppm, the IV of the cooling fluid is about 110 to 120 grams I₂/100 grams fluid, the Acid value of the cooling fluid is less than 0.06 milligrams KOH/gram, the initial dielectric breakdown voltage of the cooling fluid is greater than 35 kV (measured with a 2.0 mm gap), and the dissipation factor at 25° C. of the cooling fluid is less than 0.2%, and the dissipation factor at 90° C. of the cooling fluid is less than 2.0%. Additional properties of the cooling fluid are set out in Table 1-1.

The results of Table 1-1 show the advantage of the soybean-based cooling fluid compared to conventional mineral oil-based and PAO-based cooling fluids. For example, the highest possible (open cup) flash point for conventional mineral oils and PAOs is between 150° C. and 220° C., which is much lower than the flash point of the soybean oil-based cooling fluid (at least 315° C.).

TABLE 1-1

| Property | Observation/Value | | Measurement Method |
|---|---|---|---|
| Appearance | Clear, teal colored liquid | | Visual inspection |
| Density at 25° C. | 0.92 | g/mL | AOCS/ASTM |
| Closed cup flash point | >250° | C. | ASTM D93 |
| Viscosity (Kinematic) | 32 to 33 cSt at 40° C. | | ASTM D445 or D80 |
| Open cup flash point | >315° | C. | ASTM D92 |
| Fire point | >345° | C. | ASTM D92 |

| | | |
|---|---|---|
| Odor | Pleasant without a strong | — |
| | sage odor | |

### Example 2—Study on Odor Masking Agents

### Materials

The nature of a changed perception of odor by using low levels (1 to 100 ppm) masking agents was tested using multiple sources of masking agents for various soybean oils (SBO) of the cooling fluid of the present invention. The soybean oils utilized are set out below in Table 2-1. RBD SBO 1, RBD SBO 2, RBD SBO 3, and RBD SBO 4 are all refined bleached and deodorized. The first three RBD SBO's are aged and exhibit the odor profiles set out in Table 2.1. The fourth (RBD SBO 4) is not aged and has similar physical properties as set forth for cooling fluid of Table 1-1 and in addition exhibits an AV of less than 0.06 mg KOH gram, a dielectric dissipation factor of less than 2% at 90° C., a dielectric strength of at least 15 kV with a 2.0 mm gap, has less than 200 ppm water, an IV of 120 to 140 g I₂/g, and a melting point of −10° C.

TABLE 2-1

| Types of SBO | Original smell |
|---|---|
| RBD SBO 1 | Rancid |
| RBD SBO 2 | Rancid |
| RBD SBO 3 | Rancid |
| RBD SBO 4 | Normal |

Additional details of RBD SBO 1 through RBD SBO 4 are set out below:
RBD SBO 1: Aged 29 months
RBD SBO 2: Aged 18 months
RBD SBO 3: Aged 22 months
RBD SBO 4: Unaged

### Odor Testing

For the odor testing, a stock solution of each odor masking agent is prepared at a concentration of 2,000 ppm. The stock solution for each odor masking agent is added to the vegetable oils indicated in Table 2-2 to reach concentration of 1,000 ppm, 500 ppm, 300, 200 ppm, 100 ppm, etc. until the vegetable oil with added odor masking agent reached a level that was just “too strong” (this is indicated as “Too Strong in Table 2-2), then each of the samples was further diluted with the indicated vegetable oil to reach lower concentration incrementally in 10 ppm concentration reductions (e.g. 100 ppm to 90 ppm to 80 ppm, etc. until each of the indicated samples reached a concentration where a panel of 6 people (a mixture of males and females of varying ethnic backgrounds) (the “odor panel”) could not recognized the odor masking agent distinctive fragrance/odor, but the overall odor of the sample was pleasant (“Effective upper level”), and then each of the samples was diluted in additional 10 ppm increment until reaching to the level that the odor masking agent barely masked the vegetable oil smell to the Odor Panel (this is indicated as the “Effective lower level” in Table 2-2), and stopped when the panel of persons smelled nothing but just oil itself with the original odor profile. The equation used for diluting was ppm(current)×volume(current)=ppm(new)×volume (new). The Odor Sensory test procedure are carried out in a room at room temperature and equipped with a table and chairs, free of noise and odors, and notes were taken of comments that the Odor Panel members made while evaluating the odor of each sample tested at each of the concentrations tested. Before testing, the members of the Odor Panel are not subjected to strong odors and are not allowed to smoke or ingest coffee, soft drinks, or food for about thirty minutes prior to odor testing commencing. Samples tested are contained in 120 mL jars with lid sealed for two hours prior to testing, then opened immediately before testing. During the odor analysis, each panelist held the sample jar so that his or her nostrils are located 1 to 2 inches from the top of the open jar. As soon as practical after removing the lid, the panelist inhales deeply and focuses on detecting odors from the sample. Perceptions of each sample test are noted at first exposure and after a longer exposure, then recorded on the evaluation sheet. At an “effective lower level”, panelists would look for the fragrance level that was not easily recognizable to the odor masking agent being tested, but was enough to cover the vegetable oil smell. At an “effect upper level”, panelist would look for the fragrance level that covered the oil smell but felt pleasant without recognizing the fragrance. At the fragrance level that they could easily recognize the fragrance level, they would record that level as “Too strong level”. Regarding the aged RBD samples, all except one (SBO-RBD-4) had a rancid smell that was described by the members of the Odor Panel as having an “off” odor, similar to the smell of fish, crayons, metal, or a sour smell.

### Results

Table 2-2 shows the results of the evaluation of cooling fluids made using RBD SBO 1 through RBD SBO 4 and various odor masking agents. As can be seen from Table 2-2, the sage oil, Spanish sage oil, rose essential oil, and the blend of lavender oil and chamomile oil all provide acceptable odor masking when utilized at appropriate concentrations. In particular Sage oil and Spanish sage oil provide excellent odor masking when used between 5 ppm and 80 ppm. And, rose essential oil and the blend of lavender oil and chamomile oil provide excellent odor masking when used between 5 ppm and 30 ppm. Further, the masking agents utilized in Samples 2-1 through 2-16 provide effective odor masking for the oils that were aged to simulate the oxidation that may occur with a vegetable oil in an electronic cooling fluid over a period of several months to several years.

The samples are also tested for thermal stability by heating to 60° C. for 2 hours. This temperature is utilized to simulate the thermal environments that the cooling fluids would be exposed to in a data center or other electronic system. While cooling fluids utilized in data centers may run between 20 to 70° C., the cooling fluids typically are maintained at a temperature of 60° C. or less, to protect the electronic equipment and minimize thermal throttling of the CPU's and GPU's utilized in the centers. Results of the thermal testing of the cooling fluids are also listed in Table 2-2. As can be seen from Table 2-2, the odor masking agents utilized in Samples 2-1 through 2-16 provide excellent odor masking when the cooling fluids are heated to 60° C. for two (2) hours.

TABLE 2-2
Odor Testing of Cooling Fluids with Odor Masking Agents in various RBD-SBO based cooling fluids

| | | | Upper | Level | | | | Thermal Stability Test |
|---|---|---|---|---|---|---|---|---|
| | | | level | where | Effective | Effective | Results | (60° C. for 2 hours, |
| Sample | Odor Masking | Oil | tested | too strong | Upper | Lower | (Pass = | Effective upper level |
| No. | Agent | Tested | (ppm) | (ppm) | level | Level | masks) | ppm samples tested) |
| 2-1 | Sage, 99% | RBD SBO | 1000 | 95 | 80 | 5 | Pass | Pass |
| | | 1 | | | | | | |
| 2-2 | Sage, 99% | RBD SBO | 1000 | 95 | 80 | 5 | Pass | Pass |
| | | 2 | | | | | | |
| 2-3 | Sage, 99% | RBD SBO | 1000 | 100 | 80 | 5 | Pass | Pass |
| | | 3 | | | | | | |
| 2-4 | Sage, 99% | RBD SBO | 1000 | 100 | 80 | 5 | Pass | Pass |
| | | 4 | | | | | | |
| 2-5 | Spanish Sage oil | RBD SBO | 1000 | 95 | 80 | 5 | Pass | Pass |
| | | 1 | | | | | | |
| 2-6 | Spanish Sage oil | RBD SBO | 1000 | 95 | 80 | 5 | Pass | Pass |
| | | 2 | | | | | | |
| 2-7 | Spanish Sage oil | RBD SBO | 1000 | 100 | 80 | 5 | Pass | Pass |
| | | 3 | | | | | | |
| 2-8 | Spanish Sage oil | RBD SBO | 1000 | 100 | 80 | 5 | Pass | Pass |
| | | 4 | | | | | | |
| 2-9 | Rose essential oil | RBD SBO | 1000 | 40 | 30 | 5 | Pass | Pass |
| | | 1 | | | | | | |
| 2-10 | Rose essential oil | RBD SBO | 1000 | 40 | 30 | 5 | Pass | Pass |
| | | 2 | | | | | | |
| 2-11 | Rose essential oil | RBD SBO | 1000 | 40 | 30 | 5 | Pass | Pass |
| | | 3 | | | | | | |
| 2-12 | Rose essential oil | RBD SBO | 1000 | 40 | 30 | 5 | Pass | Pass |
| | | 4 | | | | | | |
| 2-13 | Lavender + | RBD SBO | 1000 | 40 | 30 | 5 | Pass | Pass |
| | Chamomile | 1 | | | | | | |
| 2-14 | Lavender + | RBD SBO | 1000 | 40 | 30 | 5 | Pass | Pass |
| | Chamomile | 2 | | | | | | |
| 2-15 | Lavender + | RBD SBO | 1000 | 40 | 30 | 5 | Pass | Pass |
| | Chamomile | 3 | | | | | | |
| 2-16 | Lavender + | RBD SBO | 1000 | 40 | 30 | 5 | Pass | Pass |
| | Chamomile | 4 | | | | | | |

If the odor masking agent is utilized at too high a concentration, the workers in the area could readily identify the particular odor for the odor masking agent and often the odor will end up being too sweet and/or unpleasant to the workers.

### Example 3—Study on Coloring Agents

Ranges of colors imparted by coloring agents to the cooling fluids were tracked using various color scales as shown in Table 3-1. The colorimeter used is a Model: LCS IV/Serial Number 1910705 available from BYK-Gardner GmbH. The vegetable oil utilized for Example 3 were similar to the RBD soybean oil of Example 1. Series 1 and Series 2 used different batches of RBD soybean oil and the same blue coloring agent as described for Example 1. Series 3 used similar RBD soybean oil with the same blue coloring agent as described in Example 1, but at higher levels. Series 4 used an RBD soybean oil similar to the one used in Example 1, with a greed dye coloring agent available from Sigma-Aldrich under the trade name Solvent Green 3.

The Hunter (L, a, and b) color values are according to the color space defined by Richard S. Hunter in 1948. The CIE-Lab Values refer to color values according to the CIELAB color space defined by the International Commission On Illumination in 1975.

TABLE 3-1

| | ppm of Solvent | CIE-Lab Values | | | Hunter | | | Observed |
|---|---|---|---|---|---|---|---|---|
| Series | Blue dye | L* | a* | b* | L | a | b | Color |
| Series 1 | 0.40 | 98 | −6.3 | 14.4 | 97.4 | −6.6 | 14.5 | Yellow-Green |
| | 0.60 | 98.5 | −4.8 | 8.0 | 98 | −5.1 | 8.3 | Light Green |
| | 0.80 | 98.6 | −4.0 | 5.8 | 98.2 | −4.2 | 6.0 | Green |
| | 2.83 | 96.4 | −4.7 | 1.9 | 95.4 | −4.8 | 2.0 | Green |
| | 3.18 | 96 | −5.1 | 1.7 | 94.9 | −5.2 | 1.8 | Teal-Green |
| | 3.53 | 95.6 | −5.1 | 0.6 | 94.4 | −5.2 | 0.6 | Teal/Teal- |
| | | | | | | | | Green |
| | 3.88 | 95.1 | −5.3 | 0 | 93.7 | −5.4 | 0 | Teal-Green |
| | 4.22 | 94.8 | −5.5 | −0.6 | 93.4 | −5.6 | −0.7 | Teal |
| | 4.57 | 94.3 | −5.7 | −1.3 | 92.8 | −5.8 | −1.3 | Teal |
| | 4.91 | 94.0 | −5.9 | −1.8 | 92.3 | −5.9 | −1.9 | Teal-Blue |
| | 5.26 | 93.5 | −6.1 | −2.5 | 91.8 | −6.1 | −2.6 | Teal-Blue |
| | 5.60 | 93.2 | −6.2 | −3.0 | 91.4 | −6.3 | −3.1 | Blue |
| | 5.95 | 92.8 | −6.4 | −3.7 | 90.8 | −6.5 | −3.9 | Blue |
| | 6.29 | 92.4 | −6.6 | −4.4 | 90.3 | −6.6 | −4.5 | Blue |
| Series 2 | 3.60 | 95.2 | −5.7 | 2.4 | 93.8 | −5.8 | 2.4 | Teal Green |
| | 3.80 | 95 | −5.9 | 1.9 | 93.6 | −6.0 | 1.9 | Teal-Green |
| | 4.00 | 93.9 | −5.9 | 1.3 | 92.2 | −6.0 | 1.4 | Teal |
| | 4.20 | 94.5 | −6.1 | 1.3 | 93 | −6.2 | 1.3 | Teal |
| | 4.40 | 94.3 | −6.2 | 1.0 | 92.7 | −6.3 | 1.0 | Teal |
| | 4.60 | 93.9 | −6.3 | 0.4 | 93.9 | −6.3 | 0.4 | Teal-Blue |
| | 4.80 | 93.8 | −6.5 | 0.2 | 92.1 | −6.5 | 0.2 | Teal-Blue |
| Series 3 | 15.00 | 83.2 | −10.5 | −16.0 | 79.1 | −9.9 | 17.1 | Letters Visible |
| | 20.02 | 78.7 | −11.3 | −22.9 | 73.8 | −10.4 | −24.9 | Barely see |
| | | | | | | | | letters |
| | 25.01 | 74.6 | −11.4 | −28.9 | 69.0 | −10.3 | −32.1 | Dark, hard to |
| | | | | | | | | see letters |
| | 50.09 | 59.1 | −4.5 | −51.3 | 52.1 | −3.8 | −62.8 | Too dark to |
| | | | | | | | | see letters |

| | ppm Solvent | CIE-Lab Values | | | Hunter | | | Observed |
|---|---|---|---|---|---|---|---|---|
| Series | Green No. 3 dye | L* | a* | b* | L | a | b | Color |
| Series 4 | 0.30 | 100 | −2.8 | 5.2 | 100 | −2.9 | 5.3 | Yellow-Green |
| | 0.40 | 100 | −3.0 | 5.0 | 100 | −3.1 | 5.2 | Light Green |
| | 0.60 | 99.9 | −3.2 | 4.7 | 99.8 | −3.3 | 4.8 | Green |
| | 1.00 | 100 | −3.1 | 5.0 | 100 | −3.2 | 5.2 | Green |
| | 2.10 | 99.8 | −3.8 | 4.4 | 99.8 | −3.9 | 4.5 | Green |
| | 3.00 | 99.2 | −4.5 | 3.9 | 99 | −4.6 | 4.0 | Green |
| | 6.00 | 93.9 | −10.7 | −1.7 | 94.1 | −9.3 | −0.2 | Dark Green |

Referring to Table 3-1. Series 1 was an initial evaluation in one lot of refined, bleached, and deodorized (RBD) soybean oil (SBO) to give a general sense of color as a function of concentration of blue dye, acting as the coloring agent in this study. Series 2 was a second evaluation in a second lot of RBD-SBO over a short range of concentration. Series 3 demonstrated the opacity that occurred as the concentration of blue dye increased to the point where black print on white paper (Ariel with a font size of 36) can no longer be read through a 4 oz. Qorpak flint glass jar (120 mL volume, 2.5 mm thick wall, and 5 cm wide mouth).

The blue dye used in this study is Solvent Blue from Aakash Chemicals. Solvent Blue has a chemical name of 1,4-bis(2,4,6-trimethylphenylamino)-9,10-anthracenedione or 1,4-bis(mesitylamino)anthraquinone. It is identified by CAS No. 116-75-6 and sold by Aakash Chemicals under the trade name Akasol Blue 2BS (Solvent Blue 104).

The Hunter L, a, and b color values listed from teal-green, to teal, and to teal-blue (represented by a “L” value from 91.8 to 94.9, an “a” value from −6.5 to −5.2, and a “b” value from −2.6 to 2.4) provided a cooling fluid with pleasant color and label readability. These values corresponded to a range of concentration of blue dye from 3.2 to 5.3 ppm in a typical purified RBD SBO. The preferred teal color (represented by a “L” value from 92.2 to 93.4, an “a” value from −6.3 to −5.6, and a “b” value from −0.7 to 1.4) corresponded to a blue dye concentration of 4.0 to 4.6 ppm. As the color extended into the blue range, the cooling fluid began to darken, eventually making label reading and visibility of components more difficult. For example, when the tested blue dye was at a 15.0 ppm level, letters on the label were still visible; however, when the concentration of the tested blue dye increased to 25.0 ppm level, the cooling fluid became so darkened that the letters were hardly readable. However, when the dye used at concentrations as high as 15 ppm, it is believed that when a tank or other enclosure is filled with the cooling fluid, the circuit boards and other items in the tank will not be visible toward the bottom of the tank at concentrations above 6 ppm. In general, the coloring agent preferably is at concentrations of below 6.0 ppm.

Referring to Table 3.1, if a green colored dye is utilized to obtain a green colored cooling fluid the green color typically is represented by the Hunter color scale with a “L” value from 98.0 to 100, an “a” value from −4.6 to −2.9, and a “b” value from 4.0 to 5.3.

In general, the green coloring agent typically is used at concentrations below 15 ppm, preferably at concentrations of below 6.0 ppm (for example at concentrations from 0.4 ppm to 6 ppm).

Table 3-2 shows the impact of different grades of various vegetable oils and the resulting color values when the vegetable oils were treated with 4.5 ppm of the blue dye.

TABLE 3-2

| | Hunter values | | |
|---|---|---|---|
| Oil Source | L | a | b |
| Rapeseed oil * (Cargill) | 92.2 | −6.6 | 1.4 |
| Rapeseed oil (Cargill) ** | 93 | −7.7 | 3.3 |
| RBD SBO 4 | 92.8 | −6.1 | −0.8 |
| RBD SBO 3 | 92.6 | −7.3 | 1.7 |
| RBD SBO 2 | 92.2 | −6.9 | 2.1 |
| RBD SBO 1 | 93 | −6 | −1.1 |

* similar to the rapeseed oil set out in Example 5, except aged ten (10) months
** unaged and similar to the rapeseed oil set out in Example 5

### Example 4—Impact of Odor Masking Agents on Dielectric Dissipation Factor (Tan δ) for Cooling Fluids Comprising a Vegetable Oil, Such as RBD Soybean Oil

A soybean oil similar to the soybean RBD-SBO 4 was mixed with the odor masking agents indicated in Table 4 at the concentrations listed in Table 4. After about two weeks, the dielectric dissipation factor was measured for each of the samples (4-1 (control) and 4-2 through 4-5), showing that the dissipation factor remains stable.

As can be seen from Table 4, the odor masking agents shown do not appreciably increase the dielectric dissipation factor compared to the RBD-SBO 4 alone. In particular, all the odor masking agents when utilized at the concentrations shown in Table 4 exhibited a dielectric dissipation factor of less than 2% at 90° C. and less than 0.2% at 25° C.

Table 4 demonstrates that the odor masking agents of the invention can be used at the concentrations described herein, without detriment to the electrical properties of the cooling fluid. Additionally, while not shown, the coloring agent will not significantly increase the dielectric dissipation factor of the cooling fluids, which with the odor masking agent and the coloring agent included will still be less than 2% at 90° C.

TABLE 4

| | Dielectric Dissipation Factor (tan δ) in percent (%) | | | |
|---|---|---|---|---|
| | | tan δ | tan δ | tan δ |
| Sample | Odor Masking | (25° C., | (90° C., | (100° C., |
| No. | Agent/Concentration | 60 Hz) | 60 Hz) | 60 Hz) |
| 4-1 | None (Control) | 0.0300 | 0.526 | 0.765 |
| 4-2 | Sage/80 ppm | 0.135 | 1.064 | 1.235 |
| 4-3 | Spanish Sage/80 ppm | 0.101 | 1.211 | 1.585 |
| 4-4 | Rose essential oil/30 ppm | 0.127 | 0.670 | 0.811 |
| 4-5 | Lavender & Chamomile/30 ppm | 0.080 | 0.867 | 1.216 |

### Example 5—Cooling Fluids Comprising Several Vegetable Oils with Odor Masking Agents

Odor testing was carried out in a similar manner as set forth for Example 2. The oils used for this example were as follows:

### Rapeseed Oil (RSO):

An unaged refined bleached and deodorized (RBD) oil that has been treated and has the following properties: a water content of less than 200 ppm, an IV of about 130 grams I₂/100 grams oil, an Acid value of less than 0.06 milligrams KOH/gram, a dielectric breakdown voltage of at least 15 kV (measured with a 2.0 mm gap), a dissipation factor at 25° C. of less than 0.2%, a dissipation factor at 90° C. of less than 2.0%, a closed cup flash point of at least 250° C., a viscosity from 35 to 36 cSt at 40° C., an open cup flash point of at least 315° C., a fire point of at least 345° C., and a pleasant odor.

### Sunflower Oil (SFO):

An unaged refined bleached and deodorized (RBD) oil that has been treated and has the following properties: a water content of less than 200 ppm, an IV of about 130 grams I₂/100 grams oil, an Acid value of less than 0.06 milligrams KOH/gram, a dielectric breakdown voltage of at least 15 kV (measured with a 2.0 mm gap), a dissipation factor at 25° C. of less than 0.2%, a dissipation factor at 90° C. of less than 2.0%, a closed cup flash point of at least 250° C., a viscosity of about 33 cSt at 40° C., an open cup flash point of at least 315° C., a fire point of at least 345° C., and a pleasant odor.

### Corn Oil (CO):

A refined bleached and deodorized (RBD) oil that has been treated and has the following properties: a water content of less than 200 ppm, an IV of about 120 grams I₂/100 grams oil, an Acid value of less than 0.06 milligrams KOH/gram, a dielectric breakdown voltage of at least 15 kV (measured with a 2.0 mm gap), a dissipation factor at 25° C. of less than 0.2%, a dissipation factor at 90° C. of less than 2.0%, a closed cup flash point of at least 250° C., a viscosity of about 34 cSt at 40°, an open cup flash point of at least 315° C., a fire point of at least 345° C., and a pleasant odor.

Table 5 shows that the odor masking agents tested all provided excellent odor masking characteristics and thermal stability. In this Example, a blend of white tea oil and aloe oil was tested in addition to the other odor masking agents tested in Example 2. As can be seen from Table 5, the odor masking agents required a bit higher concentration to fully and effectively be utilized with Sunflower oil, but also could be used at higher concentrations in sunflower oil without giving off too strong an odor.

TABLE 5

| | | | | | | | Thermal Stability Test |
|---|---|---|---|---|---|---|---|
| | | Upper level | Level where | Effective | Effective | Results | (60° C. for 2 hours, |
| Odor Masking | Aged Oil | tested | too strong | Upper | Lower | (pass = | Effective upper-level ppm |
| Agent | Tested | (ppm) | (ppm) | level | Level | masks) | samples tested) |
| Sage, 99% | RSO | 1000 | 70 | 50 | 5 | Pass | Pass |
| Sage, 99% | SFO | 1000 | 100 | 90 | 10 | Pass | Pass |
| Sage, 99% | CO | 1000 | 90 | 70 | 5 | Pass | Pass |
| Spanish Sage oil | RSO | 1000 | 70 | 50 | 5 | Pass | Pass |
| Spanish Sage oil | SFO | 1000 | 110 | 100 | 10 | Pass | Pass |
| Spanish Sage oil | CO | 1000 | 90 | 70 | 10 | Pass | Pass |
| Rose essential oil | RSO | 1000 | 85 | 60 | 5 | Pass | Pass |
| Rose essential oil | SFO | 1000 | 100 | 90 | 10 | Pass | Pass |
| Rose essential oil | CO | 1000 | 90 | 70 | 5 | Pass | Pass |
| Lavender + Chamomile | RSO | 1000 | 50 | 40 | 5 | Pass | Pass |
| Lavender + Chamomile | SFO | 1000 | 60 | 50 | 5 | Pass | Pass |
| Lavender + Chamomile | CO | 1000 | 40 | 30 | 5 | Pass | Pass |
| White Tea + Aloe | RSO | 1000 | 70 | 60 | 5 | Pass | Pass |
| White Tea + Aloe | SFO | 1000 | 110 | 100 | 10 | Pass | Pass |
| White Tea + Aloe | CC | 1000 | 60 | 50 | 5 | Pass | Pass |

1. A cooling fluid for cooling an electronic device in a cooling system, comprising:
a. one or more vegetable oils;
b. one or more odor masking agents; and
c. one or more coloring agents;
wherein the odor masking agent is present at a concentration sufficient to mask one or more odor attributes of the cooling fluid and wherein the odor masking agent is present at a concentration less than 100 ppm.

2. The cooling fluid of claim 1, wherein
a. the vegetable oil is selected from the group consisting of soybean oil, rapeseed oil, safflower oil, sunflower oil, corn oil, hemp seed oil, canola oil, and any combinations thereof;
b. the vegetable oil has an open cup flash point of at least 300° C.;
c. the vegetable oil has a closed cup flash point of at least 245° C.;
d. the vegetable oil has a viscosity of from about 25 to 40 cSt at 40°;
e. the vegetable oil has a moisture content of from about 10 to 200 ppm; and/or
f. the vegetable oil has an acid value of at or below about 0.06 milligrams KOH/gram oil.

3.-7. (canceled)

8. The cooling fluid of claim 1, wherein the cooling fluid has
a. a fire point of at least 340° C.; and/or
b. a breakdown voltage of at least 15 kilovolts when measured with a 2.0 mm gap distance.

9. The cooling fluid of claim 1, wherein the masking agent is an aromatic compound and selected from the group consisting of sage oil, Spanish sage oil, rose essential oil, lavender oil, chamomile oil, a blend of white tea oil and aloe oil, a blend of lavender oil and chamomile oil, and any combinations thereof.

10. The cooling fluid of claim 1, wherein
a. the odor masking agent is selected from sage oil, Spanish sage oil, and mixtures thereof, and the concentration of a sage oil, Spanish sage oil, or mixtures thereof, is in a range of 2 to 80 ppm or in a range of 10 ppm to 70 ppm based on the total weight of the cooling fluid;
b. the odor masking agent is selected from the group consisting of lavender, chamomile, and a blend of lavender and chamomile, and the concentration of the odor masking agent is from about 2 ppm to about 35 ppm based on the total weight of the cooling fluid;
c. the odor masking agent is rose essential oil, and the concentration of the odor masking agent is in a range of 2 ppm to 35 ppm or in a range of 10 ppm to 25 ppm; and/or
d. the odor masking agent is a blend of lavender oil and chamomile oil, and the concentration of the odor masking agent is in a range of 2 ppm to 35 ppm.

11.-14. (canceled)

15. The cooling fluid of claim 1, wherein
a. the coloring agent is present at a concentration sufficient to impart a desirable color to the cooling fluid while maintaining a translucency level of the cooling fluid such that the cooling fluid is capable of being seen through;
b. the coloring agent imparts a color to the cooling fluid that distinguishes the cooling fluid from one or more fluids present or near in the cooling system;
c. the color imparted to the cooling fluid by the coloring agent is selected from the group consisting of a teal color, a yellow green color, a green color, a green-teal color, a blue-teal color, and a blue color; and/or
d. the coloring agent is oil soluble.

16.-19. (canceled)

20. The cooling fluid of claim 1, wherein the cooling fluid has a Hunter color represented by
a. a “L” value from 92.2 to 93.4, an “a” value from −6.3 to −5.6, and a “b” value from −1.3 to 1.4;
b. a “L” value from 91.8 to 93.9, an “a” value from −6.5 to −5.9 and a “b” value from −2.6 to 0.4;
c. a “L” value from 93.6 to 94.9, an “a” value from −6 to −5.2, and a “b” value from 0 to 2.4;
d. a “L” value from 97.4 to 99, an “a” value from −6.6 to −5.1, and a “b” value from 8.3 to 14.5;
e. a “L” value from 95.0 to 99, an “a” value from 5.1 to −4.2, and a “b” value from 2.0 to 8.3;
f. a “L” value from 91.8 to 94.9, an “a” value from −6.5 to −5.2, and a “b” value from −2.6 to 2.4;
g. a “L” value from 97.4 to 100, an “a” value from −6.6 to −4.2, and a “b” value from 2 to 14.5; or
h. a “L” value from 94.0 to 100, an “a” value from −9.3 to −2.9, and a “b” value from −0.2 to 5.3.

21. (canceled)

22. (canceled)

23. The cooling fluid of claim 1, wherein
a. the coloring agent is a blue dye present at a concentration less than 15 ppm, or less than 3.2 ppm based on the total weight of the cooling fluid; or
b. the coloring agent is a greed dye and is present at a concentration less than 6 ppm based on the total weight of the cooling fluid.

24.-26. (canceled)

27. The cooling fluid of claim 1, further comprising an antioxidant present at a concentration between 0.15 wt % and 0.55 wt %.

28. The cooling fluid of claim 1, wherein the cooling system is a tank type immersion cooling system.

29. A cooling fluid for cooling an electronic device in a tank-type immersion cooling system, comprising:
a. a soybean oil;
b. a sage oil; and
c. a blue dye;
wherein the sage oil is present at a concentration sufficient to mask one or more odors of the soybean oil without delivering a specific and/or identifiable odor profile of the sage oil, and the blue dye imparts a teal color to the cooling fluid that distinguishes the cooling fluid from one or more fluids present in the tank-type immersion cooling system.

30.-33. (canceled)

34. The cooling fluid of claim 1, wherein
a. the one or more vegetable oils are selected from the group consisting of rapeseed oil, canola oil, safflower oil, soybean oil, sunflower oil, corn oil, hemp seed oil, and mixtures thereof;
b. the one or more odor masking agents are selected from the group consisting of sage oil, Spanish sage oil, rose essential oil, lavender, chamomile, a blend of lavender and chamomile, a blend of white tea oil and aloe oil, and mixtures thereof; and
wherein the cooling fluid has
i. a melting point of from about −25° C. to 1° C.;
ii. a closed cup flash point of 200° C. or at least 245° C.;
iii. a Cleveland Open Cup (COC) flash point of at least 200° C., or at least 315° C.;
iv. a fire point of at least 150° C.;
v. an acid value of less than 0.06 mg KOH/g, or less than 0.05 mg KOH/g;
vi. a moisture content of less than 200 ppm;
vii. a viscosity of from 28 to 40 cSt at 40° C. or from about 30 to 37 cSt at 40° C.;
viii. an initial dielectric breakdown strength of at least 15 kV (measured with a 2.0 mm gap distance);
ix. a dissipation factor (tan δ) at 25° C. of less than 0.2%; and
x. dissipation factor (tan δ) at 90° C. of less than 2.0%; and
wherein the masking agent is present at a concentration of less than 100 ppm.

35.-59. (canceled)

60. A method of using a cooling fluid to remove heat from an electronic device, the method comprising:
utilizing the cooling fluid of claim 1 to remove heat from the electronic device.

61. The method of any claim 60, wherein the electronic device is contained within a tank and the cooling system is a tank type immersion cooling system.

62. The method of claim 60, wherein a heat conductive device is attached to the electronic device, a heat exchanger situated remote to the electronic device, a cooling fluid conductive path to operatively connect the heat exchanger and the heat conductive device, and a pump to circulate cooling fluid between the heat conductive device and the heat exchanger; wherein, optionally, the heat conductive device comprises a thermal plate in physical contract with at least part of the electronic device.

63. (canceled)

64. The method of claim 60, wherein the part of the electronic device in physical contact with the thermal plate comprises a graphical processing unit (GPU), artificial intelligence enabled computing units, central processing unit (CPU), memory devices, data processing units, or combinations thereof.

65. The method of claim 60, wherein the electronic device is selected from a group consisting of a datacenter, a computer server, a crypto mining machine, a high-heat generating computer, a high performance computing center, an artificial intelligence computing center, and an electric vehicle charging station.

66. An electronic device comprising: electronic components, a cooling system, and the cooling fluid of claim 1.

67. (canceled)

68. The cooling fluid of claim 1, wherein the vegetable oil utilized has a Lovibond RYBN Colour of: Lovibond Red less than 2.0;
and a Lovibond Yellow below 20.

69. The cooling fluid of claim 1, wherein the vegetable oil is refined bleached and deodorized and treated with clays or activated carbon to reduce a Lovibond RYBN Colour to the values set forth in claim 68; and the clay is selected from the group comprising: activated carbon, activated carbon that is free of dust modifiers, bleaching clays such as bentonites, kaolin clays, diatomites, activated palygorskites, activated silicas bauxite and mixtures thereof.

70.-74. (canceled)
